(19) United States
(12) Patent Application Publication
(10) Pub. No.: US 2011/0203843 A1
(43) Pub. Date: Aug. 25, 2011

(54) MULTILAYER SUBSTRATE

(76) Inventor: Taras Kushta, Tokyo (JP)

(21) Appl. No.: 12/442,238

(22) PCT Filed: Oct. 11, 2007
(86) PCT No.: PCT/JP2007/070307

§ 371 Date: Mar. 20, 2009

(30) Foreign Application Priority Data
Oct. 13, 2006 (JP) 2006-280458

(51) Int. Cl. H05K 9/00; H05K 1/11; G06F 17/50

(52) U.S. Cl. 174/377; 174/266; 716/137

(57) ABSTRACT

To provide more compact dimensions of a via structure formed by signal via pairs and ground vias in multilayer substrate. A multilayer substrate is provided such that the multilayer substrate comprising a high-isolated via cell wherein the high-isolated via cell comprises: two signal via pairs; a shield structure around two signal via pairs consisting of ground vias and ground strips connected to ground vias wherein the shield structure is formed symmetrically in respect to two via pairs to reduce the transformation between mixed modes and also leakage from two signal via pairs; a clearance hole separating signal via pairs from other conductive parts of the multilayer substrate and having predetermined dimensions to provide broadband operation of the high-isolated via cell; and the separating strip disposed symmetrically between said signal via pairs to provide crosstalk reduction between two signal via pairs and common mode decrease.

This application is based upon and claims the benefit of priority from Japanese patent application No. 2006-280458, filed on Oct. 13, 2006, the disclosure of which is incorporated herein in its entirety by reference.

### TECHNICAL FIELD

The present invention relates to a multilayer substrate used for differential signaling in which vertical transitions between planar conductor layers of the substrate are formed as a high-isolated cell consisting of two signal via pairs, a shielding structure around the signal via pairs, clearance hole separating the signal via pairs from other conductive parts of the multilayer substrate, strip segment between signal via pairs serving for the reduction of the crosstalk effects between the signal via pairs and common mode suppression in the area of the vertical transitions.

Also, this invention gives structures for the crosstalk effect reduction by means of both the use of ground via shield around the signal via pairs and an appropriate arrangement of the signal vias disposed within the ground via shield providing the intercrossing differential signaling.

### BACKGROUND ART

A multilayer substrate technology is a cost-effective approach to design high-speed and high-density interconnection circuits. The multilayer substrate includes a number of planar conductor layers separated by an isolated material and serving for distribution of signal, ground, and power circuits. Signal interconnections including differential ones at the planar conductor layers can be developed on the base of planar transmission lines such as microstrip lines, strip lines, coplanar lines, slot lines, and so on. The vertical connections between planar conductor layers of the multilayer substrate can be provided by means of different types of via structures, as for an example through hole vias, blind vias, and buried vias.

Differential signaling is one of the effective approaches to improve electrical and electromagnetic interference (EMI) performances of high-speed interconnected circuits. It is formed by two pulses of opposite polarity propagating in a conductor pair. The use of the differential signaling in the multilayer substrate can lead to following advantages: 1) Removing noise from ground system; 2) Providing immunity of a differential receiver to the common mode; 3) Reducing radiating emission.

A differential planar transmission line in the multilayer substrate is usually formed by signal strip pair conjointly with ground plates that give an improvement of the shielding and impedance controlling properties of the planar transmission line.

Differential vertical interconnections in a high-density structure based on the multilayer substrate are usually provided by two signal vias. The grounding around the signal via can be formed by means of ground vias.

However, in this case, a problem of a deficit of space for an appropriate arrangement of ground vias around the signal via is met with the high-density structure. Also, problems of crosstalk effect between signal via pairs and transformation between the differential and common modes arise.
Moreover, providing the wideband operation of the vertical interconnections in the multilayer substrate is another issue which has to be resolved in high-speed design.

Ground vias around a signal via are used to provide a vertical interconnection in multilayer substrate. (see Patent Document 1) However, the use of ground vias around the each signal via can lead to necessity of additional space in high-density configurations and the cost increase that are problematical in many cases of practical structures.

Signal vias are placed in a multilayer substrate in the area of the clearance hole. (see Patent Document 2) However, in considered document, there are no ground vias around the signal vias providing both shielding and additional characteristic impedance control. Also coupling (crosstalk effect) between vias can be high enough in presented structures.

A differential via pair separated from other conductive parts of the multilayer printed circuit board (PCB) by a clearance hole is presented. (see Patent Document 3) However, in this document, ground vias around the signal via pair are not used. But it should be noted that the ground via effect is very important, because it leads to not only shielding but also to additional degree of freedom for characteristic impedance control in the differential via pair.

According to the drawings a multilayer substrate including a via structure is shown in FIGS. 1A, 1B, 1C, and 1D. The via structure is formed by two differential via pairs. The multilayer substrate can be consisted of a number of planar conductor layers separated by an isolated material. These planar conductor layers can serve for forming the signal traces, providing the grounding and supplying power. In a presented example of the multilayer substrate, an arrangement of functions of the planar conductor layers is as following: Layers 1L2, 1L4, 1L7, 1L9, 1L11, and 1L13 act as ground planes 106; Layers 1L5 and 1L6 are for power supply 107; Layers 1L1, 1L3, 1L8, 1L10, 1L12 and 1L14 serve to form signal paths 108. Also in considered case, one via pair is formed by signal vias 101 and 102 and another via pair is consisted of signal vias 103 and 104. Each signal via includes metallized through hole with outer diameter and pad with diameter d_{pad} (see FIGS. 1C and 1D). The signal via is separated from other conductive parts of the multilayer substrate by a circular clearance hole 105 with diameter of d_{cle}.

Here, the electrical performance of the via structure in the multilayer substrate shown in FIGS. 1C and 1D is estimated for the following dimensions: dᵣ=0.25 mm; d_{pad}=0.5 mm; d_{cle}=0.7 mm. Note the distance between the center of the signal vias (marked “I₁” in FIG. 1C) is 1.0 mm in both differential pairs, and the distance between via pairs, I₂, is also 1.0 mm, that is I=I₁=I₂. The multilayer substrate in considered example is in the form of a multilayer PCB consisting of fourteen copper planar conductor layers isolated by the FR-4 material with the relative permittivity of □ᵣ=4.2 as assumed in simulations. Spaces between planar conductor layers (see FIG. 1D) are: H₁=0.2 mm, H₂=0.385 mm, H₃=0.2 mm, H₄=0.52 mm and H₅=0.15 mm; the thickness of conductor planes embedded in the PCB is 0.035 mm; the thickness of top and bottom conductor planes is 0.055 mm.

To estimate the electrical performance of the via structure shown in FIGS. 1C and 1D, two stripline pairs are connected to the differential via pair at 3rd and 12th layers, respectively. In FIG. 1E, a cross-sectional view of the via structure at 3rd conductor layer including the connection of the strip pair and the differential via pair is shown. The similar cross-sectional view is for the multilayer substrate at 12th conductor layer. In the case considered here, the differential characteristic impedance of the stripline pairs is about 100 Ohms and is provided by following dimensions of the stripline pair: w=0.09 mm and s=0.2 mm.

Leakage loss of the differential mode for considered via structure can be estimated by the S-parameters according to following formula:

$$\frac{{P}_{leak}}{{P}_{inc}} = 1 - {\vert {S}_{11}^{DD} \vert}^{2} - {\vert {S}_{21}^{DD} \vert}^{2} , \qquad ( 1 )$$

where P_{inc} is the incident power, Pₗₑₐₖ is the leakage power,

|S₁₁^{DD}|

is the return loss, and

|S₂₁^{DD}|

is the insertion loss.

### Patent Document 1 JP-2003-229511

### Patent Document 2 JP-2003-31945

### Patent Document 3 US2002/0070826A1

### DISCLOSURE OF THE INVENTION

### Problems to be Solved by the Invention

To calculate the S-parameters, the finite-difference time-domain method, which is verified as one of the most accurate numerical techniques in world-wide practice, is used. In FIG. 2, the leakage losses calculated according to Eq.1 are presented in the frequency band up to 20 GHz. As follows from this figure, the leakage losses can considerably increase at higher frequencies. This effect means that the transformation of the differential mode to the common mode, radiation from the multilayer PCB, and crosstalk increase at the higher frequencies. To prevent leakage losses, a ground via shielding around a signal via or a signal via pair can be used. However, if a shielding is used around each signal via or differential signal pair, then it can lead to the increase of the space in a layout that is a critical issue in the most of the high-density structures and, moreover, to the increase of the fabrication cost.

It is an exemplary object of the present invention to provide more compact dimensions of a via structure formed by signal via pairs and ground vias in multilayer substrate and, also, to increase the isolation of the signal via pairs in the via structure. Another exemplary object is improving impedance control for via structures in the wide frequency band. Also, other exemplary objects of presented invention are decreasing crosstalk effect between signal via pairs and transformation between differential and common modes as well as increasing common mode suppression in via structures.

### Means for Solving the Problem

According to an exemplary aspect of the invention, there provided a multilayer substrate comprising a via cell is proposed.

The multilayer substrate according to the present invention is a multilayer substrate comprising a via cell wherein the via cell comprises: two signal via pairs; a shield structure around two signal via pairs consisting of ground vias and ground strips connected to the ground vias formed symmetrically in respect to each signal via pair; a separating strip disposed symmetrically between two signal via pairs; and a clearance hole providing an isolation two signal via pairs from the shield structure, filled in a non-conducting material except the area of the separating strip, and having transverse dimensions larger than an area bounded by an imaginary contour tangentially connecting outer conductor boundaries of signal vias of two signal via pairs.

The multilayer substrate may also be configured such that the separating strip is formed of a metal or an electromagnetic energy absorbing material.

The multilayer substrate may also be configured such that the shield structure is formed by ground vias and ground strips connected to the ground vias as well as power supply vias which are disposed symmetrically with respect to the nearest signal via pair of the via cell and are surrounded by the ground strips.

The multilayer substrate may also be configured such that the clearance hole has predetermined dimensions to provide a broadband operation of the via cell.

The multilayer substrate may also be configured such that an impedance matching of one signal via pair of the via cell and an interconnected circuit joined to the signal via pair is attained by adjusting diameters of vias of the signal via pair, the distance between vias of the signal via pair, the distance of the signal via pair to the shield structure, and transverse dimensions of the separating strip.

The multilayer substrate according to the present invention is a multilayer substrate comprising a via cell wherein the via cell comprises two signal via pairs in which signal vias are arranged so that an imaginary closed contour passing through the centers of the signal vias has the same side, and each signal via pair of two signal via pairs is formed by the signal vias disposed on the diagonal of the imaginary contour providing intercrossing differential signaling; a shield structure around two signal via pairs consisting of ground vias and ground strips connected to the ground vias wherein the shield structure is formed symmetrically in respect to two signal via pairs; and a clearance hole providing an isolation two signal via pairs from the shield structure, filled in a non-conducting material, and having transverse dimensions larger than an area bounded by an imaginary contour tangentially connecting outer conductor boundaries of signal vias of two signal via pairs.

The multilayer substrate may also be configured such that the imaginary closed contour passing through the centers of the signal vias has the same side shaping a square, and each signal via pair of two signal via pairs is formed by the signal vias disposed on the diagonal of the square contour providing intercrossing differential signaling.

The multilayer substrate may also be configured such that the imaginary closed contour passing through the centers of the signal vias has the same side shaping a rhombus, and each signal via pair of two signal via pairs is formed by the signal vias disposed on the diagonal of the rhombus providing intercrossing differential signaling.

The multilayer substrate may also be configured such that the shield structure is formed by ground vias and ground strips connected to the ground vias as well as power supply vias which are disposed symmetrically with respect to two signal via pairs and are surrounded by the ground strips.

The multilayer substrate may also be configured such that a clearance hole has predetermined dimensions to provide broadband operation of the via cell.

The multilayer substrate may also be configured such that an impedance matching of one signal via pair of the via cell and an interconnected circuit joined to the signal via pair is attained by adjusting diameters of vias of the signal via pair, the distance between vias of the signal via pair, and the distance of the signal via pair to the shield structure.

The multilayer substrate according to the present invention is a multilayer substrate comprising a high-isolated via cell wherein the high-isolated via cell comprises: two signal via pairs in which signal vias are arranged so that an imaginary closed contour passing through the centers of the signal vias has the same side, and each signal via pair of two signal via pairs is formed by the signal vias disposed on the diagonal of the imaginary contour providing intercrossing differential signaling; a shield structure around two signal via pairs consisting of ground vias and ground strips connected to the ground vias wherein the shield structure is formed symmetrically in respect to two signal via pairs; a separating strip cross disposed symmetrically between two signal via pairs; and a clearance hole providing an isolation two signal via pairs from the shield structure, filled in a non-conducting material except the area of the separating strip cross, and having transverse dimensions larger than an area bounded by an imaginary contour tangentially connecting outer conductor boundaries of signal vias of two signal via pairs.

The multilayer substrate may also be configured such that the imaginary closed contour passing through the centers of the signal vias has the same side shaping a square, and said signal via pairs are formed by the signal vias disposed on the diagonal of the square contour providing intercrossing differential signaling.

The multilayer substrate may also be configured such that the imaginary closed contour passing through the centers of the signal vias has the same side shaping a rhombus, and two signal via pairs are formed by the signal vias disposed on the diagonal of the rhombus providing intercrossing differential signaling.

The multilayer substrate may also be configured such that the separating strip cross is formed of an electromagnetic energy absorbing material.

The multilayer substrate may also be configured such that the shield structure is formed by ground vias and ground strips connected to the ground vias as well as power supply vias which are disposed symmetrically with respect to two signal via pairs and are surrounded by the ground strips.

The multilayer substrate may also be configured such that a clearance hole has predetermined dimensions to provide broadband operation of the via cell.

The multilayer substrate may also be configured such that an impedance matching of one signal via pair of the via cell and an interconnected circuit joined to the signal via pair is attained by adjusting diameters of vias of the signal via pair, the distance between vias of the signal via pair, the distance of the signal via pair to the shield structure, and transverse dimensions of the separating strip cross.

### BRIEF DESCRIPTION OF THE DRAWINGS

The foregoing and other exemplary purposes, aspects and advantages will be better understood from the following detailed description of an exemplary embodiment of the invention with reference to the drawings.

FIG. 1A is a drawing of a related example of a multilayer substrate including a via structure;

FIG. 1B is a drawing of a related example of a multilayer substrate including a via structure;

FIG. 1C is a drawing of a related example of a multilayer substrate including a via structure;

FIG. 1D is a drawing of a related example of a multilayer substrate including a via structure;

FIG. 1E is a drawing of a related example of a cross-sectional view of the via structure at 3rd conductor layer including the connection of the strip pair and the differential via pair;

FIG. 2 is a graph of leakage losses calculated for a via structure without ground vias.

FIG. 3A is a drawing of an exemplary embodiment of the present invention of a multilayer substrate including a high-isolated via cell;

FIG. 3B is a drawing of an exemplary embodiment of the present invention of a multilayer substrate including a high-isolated via cell;

FIG. 3C is a drawing of an exemplary embodiment of the present invention of a multilayer substrate including a high-isolated via cell;

FIG. 3D is a drawing of an exemplary embodiment of the present invention of a multilayer substrate including a high-isolated via cell;

FIG. 3E is a drawing of an exemplary embodiment of the present invention of a multilayer substrate including a high-isolated via cell;

FIG. 3F is a drawing of an exemplary embodiment of the present invention of a multilayer substrate including a high-isolated via cell;

FIG. 4A is a graph of magnitudes of the S-parameters which demonstrate clearly-expressed advantages of the high-isolated cells with optimized clearance holes;

FIG. 4 B is a graph of magnitudes of the S-parameters which demonstrate clearly-expressed advantages of the high-isolated cells with optimized clearance holes;

FIG. 4 C is a graph of magnitudes of the S-parameters which demonstrate importance of the application of separating strips to reduce crosstalk effect between signal via pairs;

FIG. 5 is a graph of leakage losses calculated for a high-isolated cell with ground shield and optimized clearance hole;

FIG. 6 is a drawing of a horizontal cross-sectional view of another high-isolated differential via cell;

FIG. 7 is a drawing of a horizontal cross-sectional view of another high-isolated differential via cell;

FIG. 8A is a drawing of a horizontal cross-sectional view of another high-isolated differential via cell;

FIG. 8B is a drawing of a vertical cross-sectional view of another high-isolated differential via cell;

FIG. 9 is a drawing of a horizontal cross-sectional view of another high-isolated differential via cell;

FIG. 10 is a drawing of a horizontal cross-sectional view of a high-isolated differential via cell with intercrossing differential signaling;

FIG. 11 is a graph of magnitudes of the S-parameters which demonstrate advantages of a high-isolated via cell with intercrossing differential signaling;

FIG. 12 is a drawing of a horizontal cross-sectional view of another high-isolated differential via cell with intercrossing differential signaling;

FIG. 13 is another graph of magnitudes of the S-parameters which demonstrate advantages of a high-isolated via cell with intercrossing differential signaling;

FIG. 14 is a drawing of a horizontal cross-sectional view of another high-isolated differential via cell with intercrossing differential signaling;

FIG. 15 is a drawing of a horizontal cross-sectional view of another high-isolated differential via cell with intercrossing differential signaling;

FIG. 16 is a graph of magnitudes of the S-parameters which demonstrate advantages of a high-isolated via cell with a separating strip made of an electromagnetic energy absorbing material;

FIG. 17 is a drawing of a horizontal cross-sectional view of another high-isolated differential via cell with intercrossing differential signaling;

### DESCRIPTION OF REFERENCE NUMERALS

101, 102, 103, 104, 301, 302, 303, 304, 1001, 1002, 1003, 1004, 1101, 1102, 1103, 1104, 1201, 1202, 1203, 1204, 1301, 1302, 1303, 1304, 1501, 1502, 1503, 1504 signal via
105 circular clearance hole
106 ground plane
107 power supply
108 signal path
305 optimized clearance hole
310, 603, 703, 803, 903, 1005, 1105, 1205, 1305, 1505 ground via
311, 606, 706, 805, 905, 1007 separating strip
312, 605, 705, 804, 904, 1006, 1106, 1206, 1306, 1506 ground strip
601, 602, 701, 702, 801, 802, 901, 902 signal differential via pair
604, 704, 1509, 1510, 1511, 1512 power supply via
607, 707, 806, 906, 1008, 1107, 1208, 1308, 1508 clearance hole
1307 separating strip cross

### BEST MODE FOR CARRYING OUT THE INVENTION

The following description of exemplary embodiments directed to only several types of high-isolated via cells in a multilayer substrate but it is well understood that this description should not be viewed as narrowing the claims which are presented here.

In this invention, multilayer substrates including high-isolated cells in interconnected circuits are proposed. The high-isolated cells are mainly formed on the base of following four points.

The first point is the ground shielding around the two signal via pairs. This shielding is formed by both ground vias and ground strips connected with each other at the conductor layers of the multilayer substrate.

The second point is a method according to which a minimal skew in the via pair is provided for differential signaling. In the method, it can be achieved by an appropriate arrangement of ground vias, corresponding width of the ground strip and symmetrical position of signal via pairs relatively to the ground shielding.

The third point is the forming of the clearance hole separating the differential via pairs from other conductive parts of the multilayer substrate with the form and dimensions providing the broadband operation of the via structure.

The fourth point is the use of specific strips at the conductor layers of a multilayer substrate disposed symmetrically between signal differential via pairs to reduce crosstalk between these differential via pairs and magnitude of the common mode.

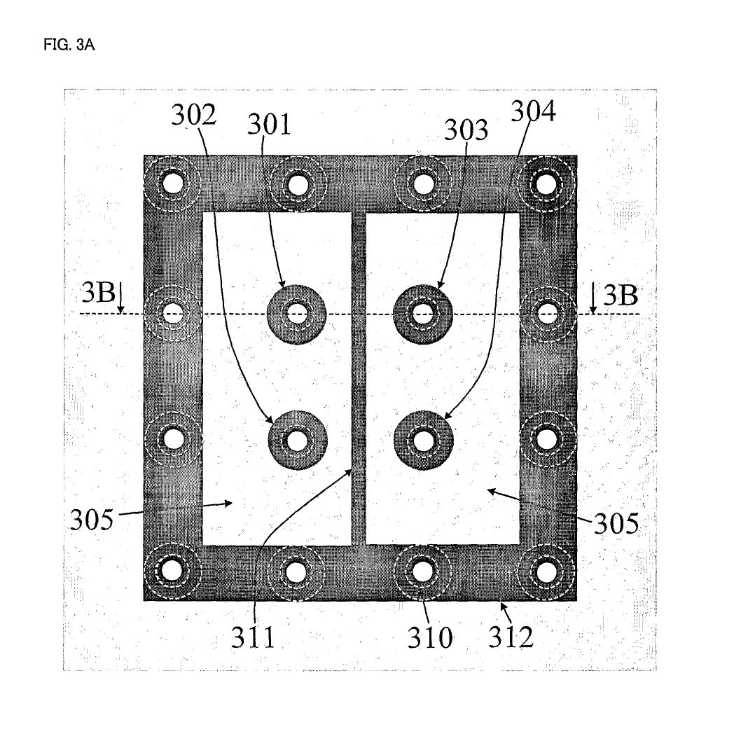

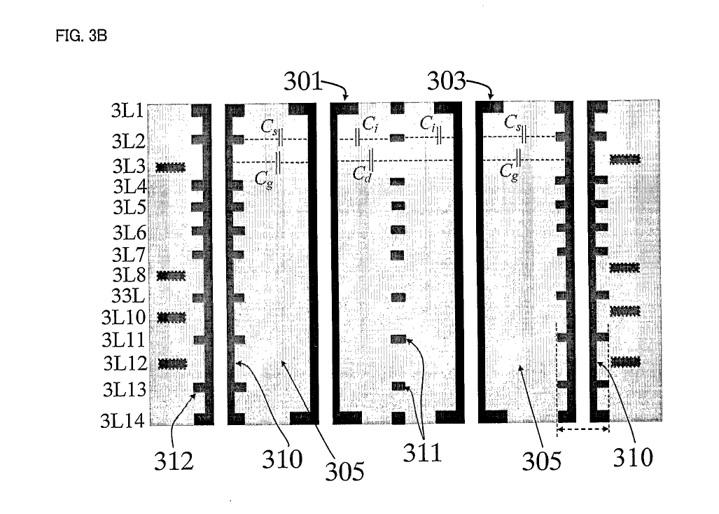

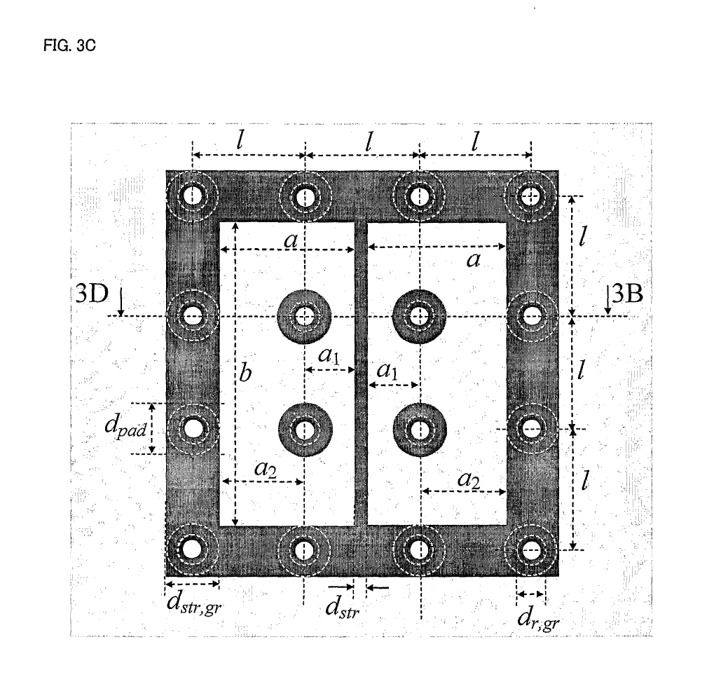

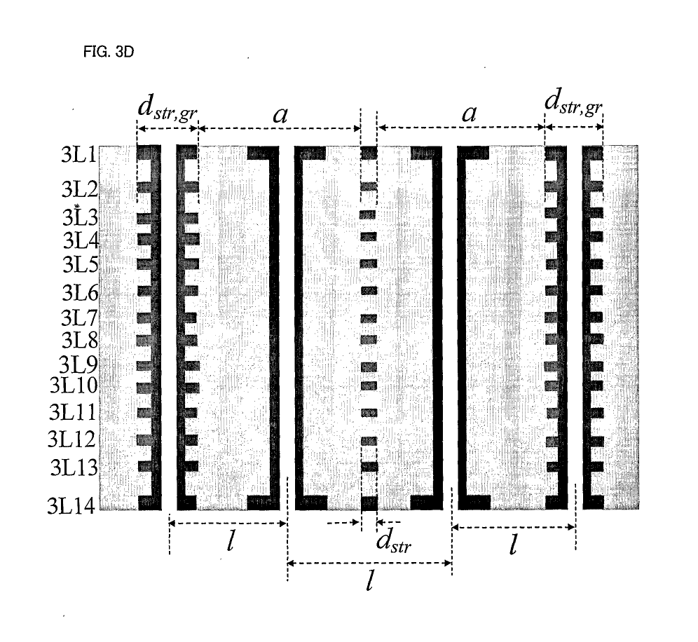

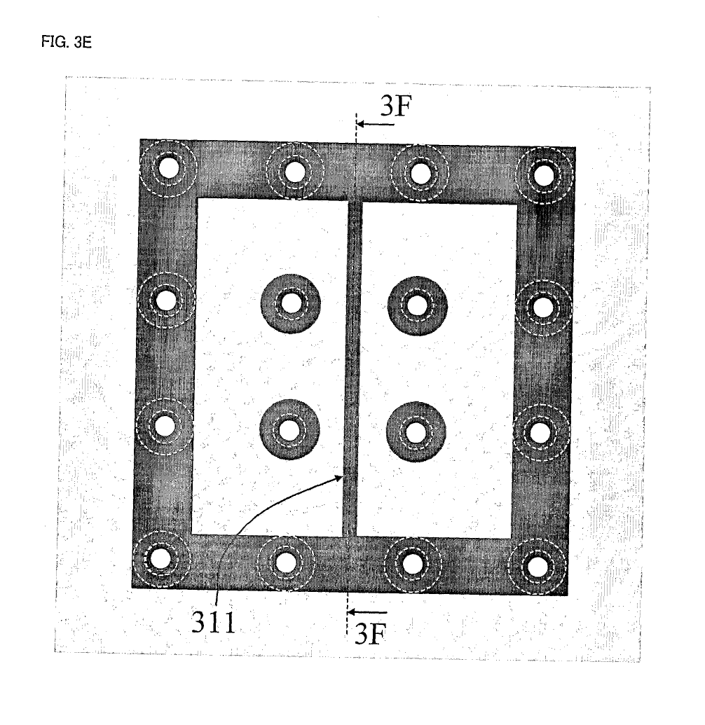

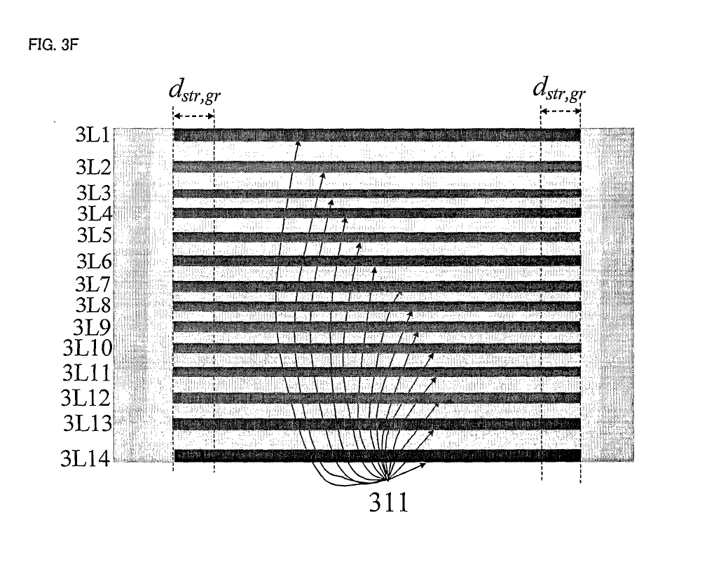

As an exemplary embodiment, in FIGS. 3A, 3B, 3C, 3D, 3E, and 3F a multilayer substrate including a high-isolated via cell is shown. The cell is obtained by the use of above-mentioned four points and consists of first signal via pair formed by signal vias 301 and 302; second signal via pair formed by signal vias 303 and 304, clearance hole 305 separating the signal vias from other conductive parts of the substrate; ground vias 310 connected to the ground strip 312 providing a high isolation of the via cell; separating strip 311 disposed symmetrically between signal via pairs at the conductor layers and serving to reduce crosstalk effect between these signal differential pairs.

The dimensions of the clearance holes 305 are defined by a way to provide a broadband operation of the via cell. As for an example, in FIG. 3B, the capacitance between the signal via 301 of the isolated cell and ground vias 310 is C_{g} and the capacitance between the signal via 301 and the ground strip 312 at a conductor layer is Cₛ. The capacitance between the signal via 301 and the separating strip 311 is Cᵢ. If there is a difference between C_{g} and Cₛ, then characteristic impedance, Z_{c}, is a variable magnitude along the vertical direction of the via cell. As a result, it is difficult to provide impedance matching in a wide frequency band between the isolating cell and other interconnected circuits. Note that characteristic impedance for the via cell can be defined as in a transmission line according to following well-known formula:

$$Z = \sqrt{\frac{L}{C}} , \qquad ( 2 )$$

where L is the distributed inductance and C is the distributed capacitance. To obtain the difference between C_{g} and Cₛ as a small value, it is necessary to provide the distance between the signal via pair and the ground vias as the same value as the distance from the signal via pair to the ground strips. It can be achieved by an appropriate choice of the clearance hole dimensions. For the via cell presented in FIGS. 3C and 3D, the dimensions of the clearance hole, providing its broadband operation and taking into account the width of a separating strip, are defined as following:

b=3I−d_{str,g·r}, (3)

a₂=I−d_{str,gr}I2, (4)

a₁=II2−dₛₜᵣI2, (5)

where I is the distance between the vias forming the isolating cells; d_{str,gr} is the width of the ground strip connecting the ground vias; dₛₜᵣ is the width of the separating strip between the signal via pairs. Note that the width of the ground strip, d_{str,gr}, can be chosen as equal to the pad diameter, d_{pad}, which is defined by dimensional tolerances of via fabrication process to provide full-value connections of the ground vias and the ground strips. Also in some design the width of the separating strip, dₛₜᵣ, can be defined as equal to the diameter of the ground via, d_{r,gr}.

Separating strip can be formed of a conductor material or an electromagnetic energy absorbing material leading to common mode reduction.

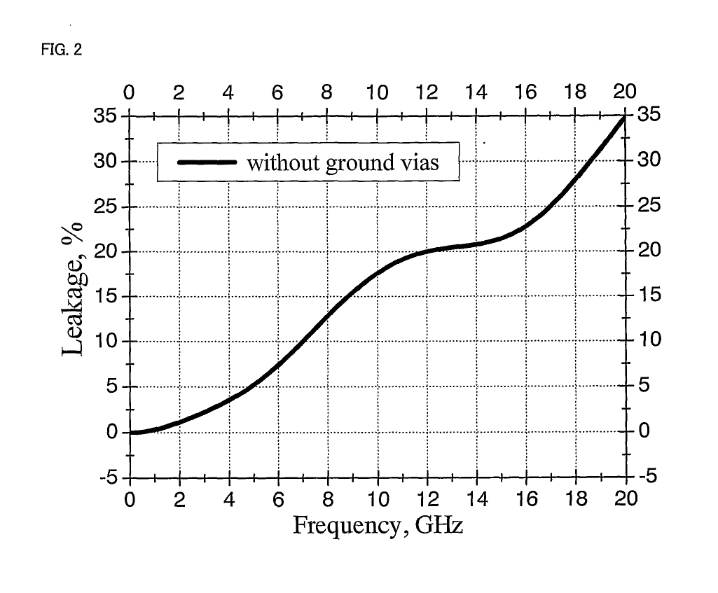

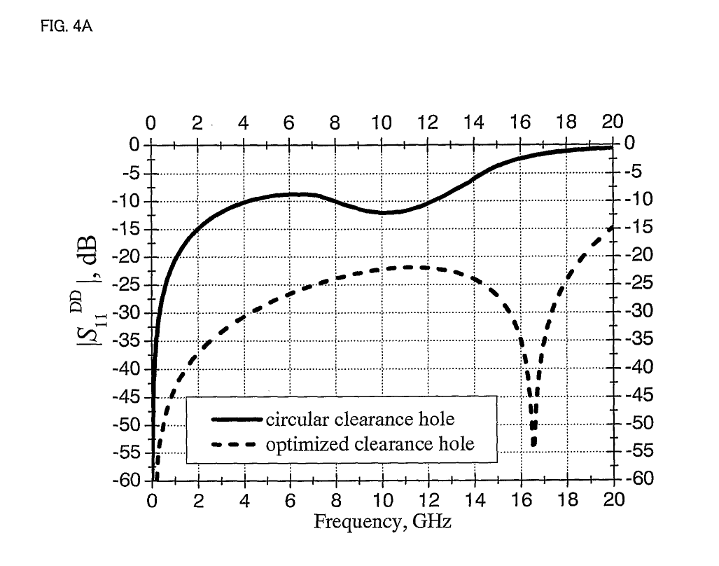

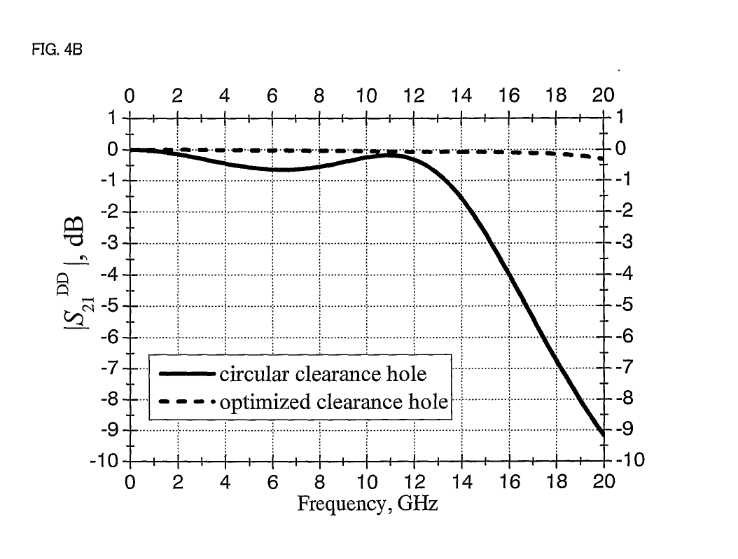

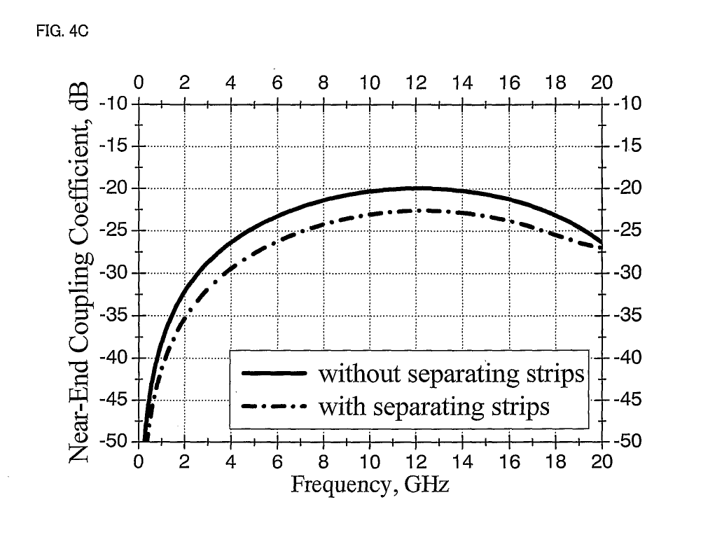

To show importance of an appropriate choice of the clearance hole in the high-isolated via cell, the data for the via cell with the commonly-used circular clearance hole and the clearance hole optimized according to Eqs.3-5 are presented in FIGS. 4A and 4B. For these figures the dimensions of the differential via pairs and the 14-conductor-layer PCB are the same as for FIG. 2. The ground vias and ground strips have the following parameters: d_{r,gr}=0.25 mm; d_{str,gr}=d_{pad}=0.5 mm; I=1.0 mm. For commonly-used clearance hole, d_{cle}=0.7 mm and for the optimized clearance hole, a₁=0.375 mm, a₂=0.75 mm, and b=2.5 mm. The width of the separating strip, dₛₜᵣ, is equal to 0.25 mm. The electrical performance of the via structures has been estimated by the similar manner as for FIG. 2, that is, differential via pairs were connected to the 100 Ohms stripline pairs at the 3rd and 12th conductor layers.

In FIGS. 4A and 4B, magnitudes of the S-parameters demonstrate clearly-expressed advantages of the high-isolated cells with optimized clearance holes.
Also, in FIG. 4C, importance of application of the separating strip to reduce the crosstalk effect between the differential signal via pair in the high-isolated via cell is demonstrated. In this figure, near-end coupling coefficients for high-isolated via cells with and without the separating strip are demonstrated. Note that dimensions and structure of the high-isolated cells in the multilayer substrate are the same as for FIGS. 4A and 4B. Only, all separating strips are removed for the case of the via cell without separating strips. As follows from FIG. 2C, the separating strips are effective elements to reduce crosstalk between signal via pairs in a high-isolated via cell.

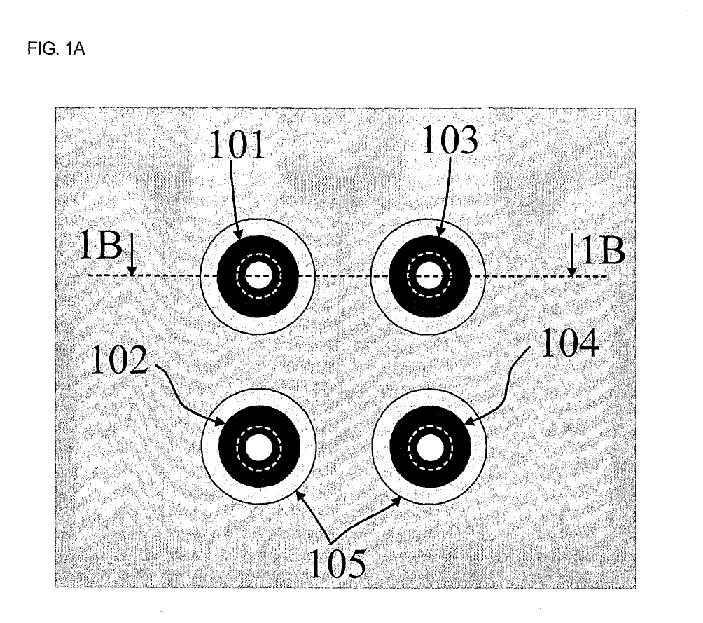

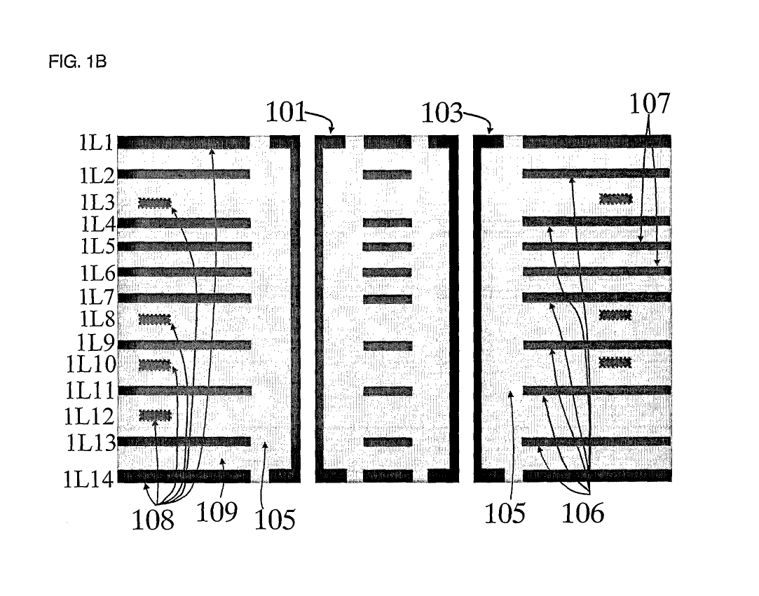

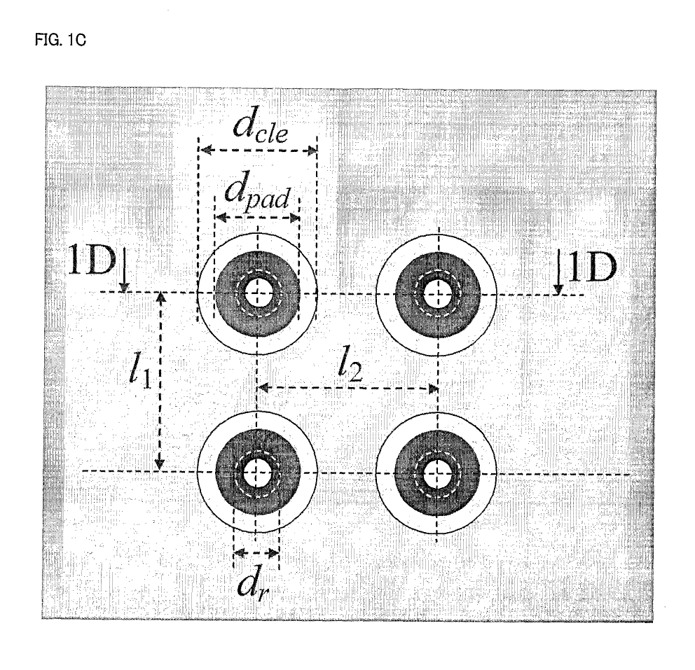

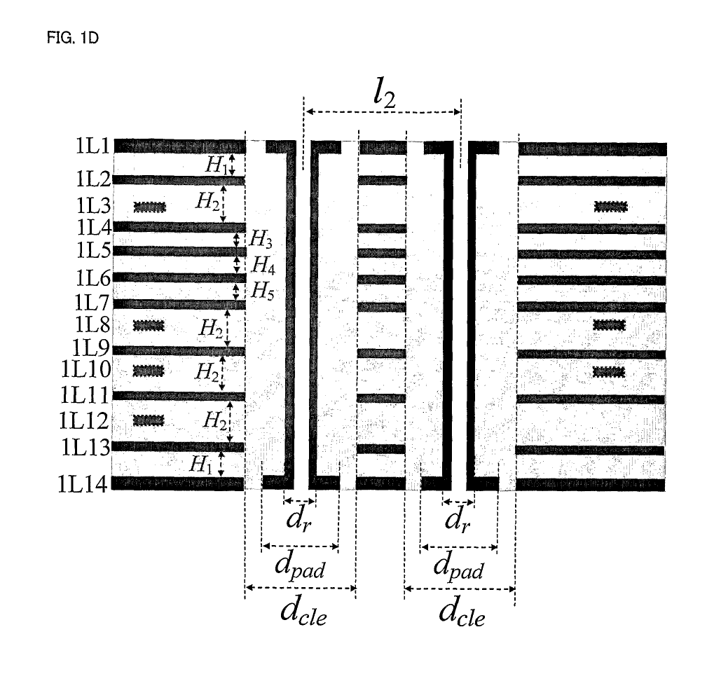

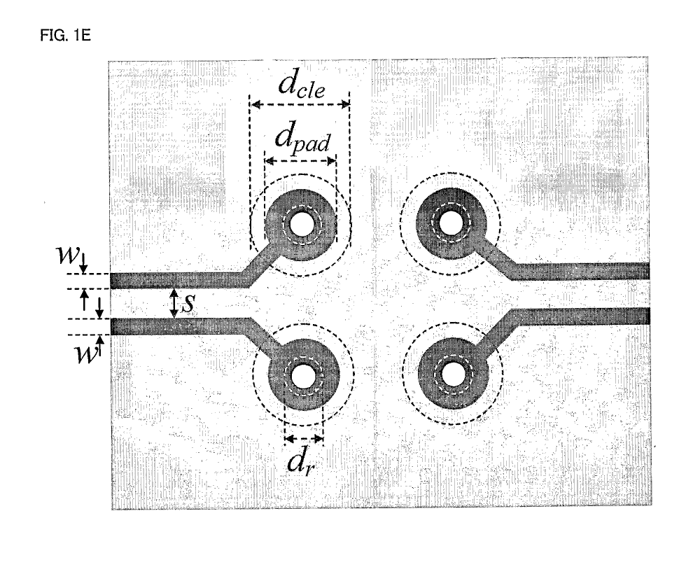

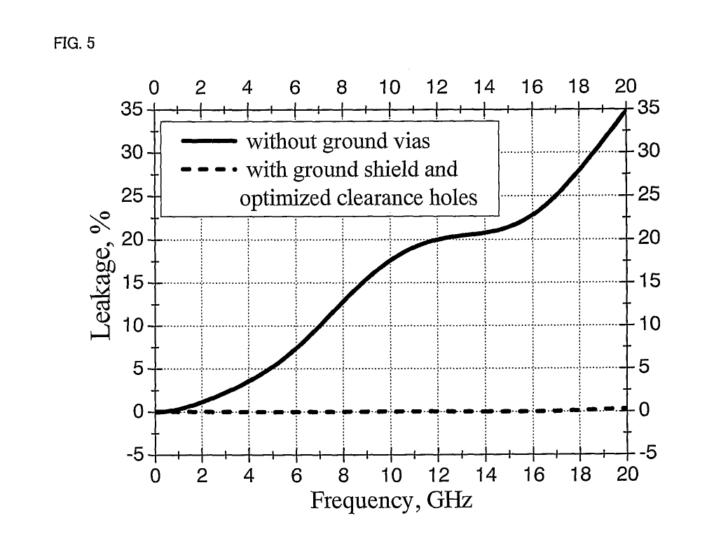

In FIG. 5, leakage losses calculated for above-mentioned high-isolated cell with optimized clearance hole is presented. For comparison in this figure, data for via structure shown in FIG. 1 are also presented. As follows from this figure, application of ground shield formed by ground vias and ground strips can practically suppress leakage losses from the differential via pairs.

In present invention, the important point is the method providing a minimal skew in the signal differential via pair. This method is based on realizing the same capacitance coupling of each signal via forming the differential pair to the ground shielding formed by ground vias and ground strips. In this case, both C_{g} and Cₛ (see FIG. 3B) for each signal via of the differential via pair have to be with the same magnitudes. It can be explained by well-known formula for the speed of the signal propagating in a transmission line as:

v=1/\sqrt{L·C}. (6)

As follows from this formula, the different capacitance coupling of the signal vias forming the signal differential via pair gives the different time of the signal propagation in the each signal via. This effect leads to skew in differential signaling and, as a result, the increase of the transformation of the differential mode to the common mode in differential interconnection circuits and, also, radiation from the differential interconnections.

In high-isolated via cell shown in FIG. 3, this condition is satisfied by the symmetrical position of the differential signal via pairs relating to the ground shielding.

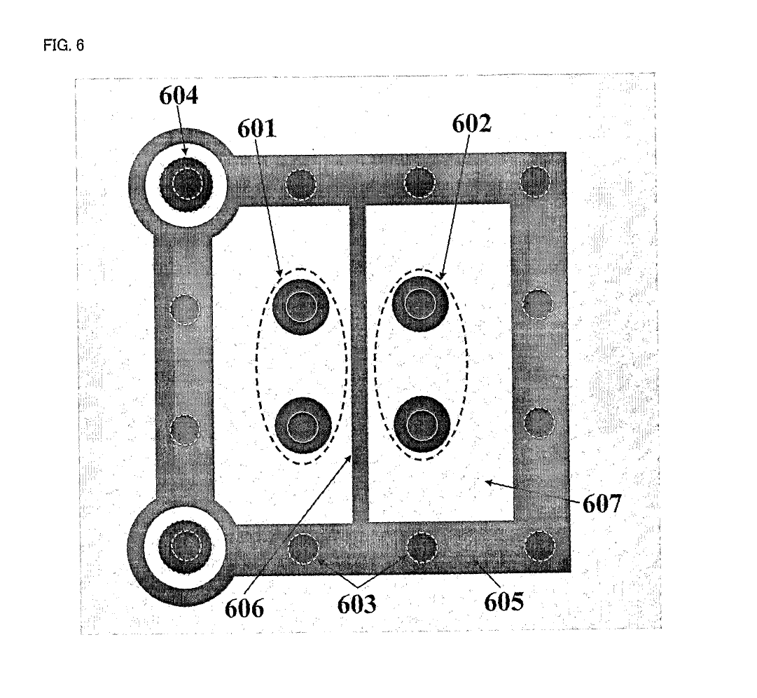

In FIG. 6, a cross-sectional view of another high-isolated differential via cell is shown. This cell includes two signal differential via pairs 601 and 602 and is surrounded by ground vias 603 and power supply vias 604. Ground vias in the cell are connected by means of the ground strip 605. The ground strip 605 is also applied for providing the shielding around the power supply vias 604. It is important to note that power supply vias 604 are arranged symmetrically relatively to the differential signal via pairs. Also, separating strip 606 serves to reduce crosstalk between differential via pairs 601 and 602. Clearance hole 607 is optimized according to above-mentioned technique.

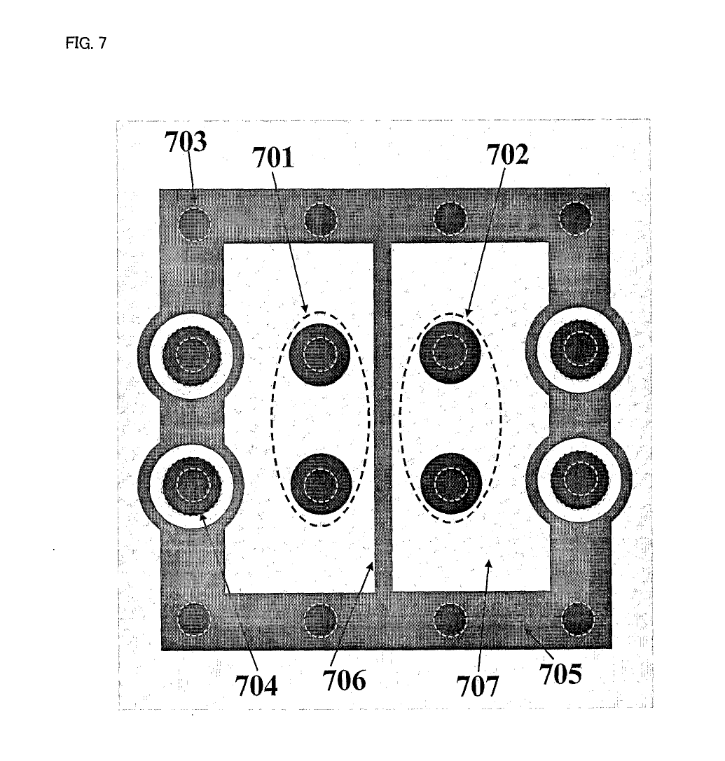

Another high-isolated differential via cell is shown in FIG. 7. In this figure four power supply vias 704 are symmetrically disposed with respect to differential via pairs 701 and 702.

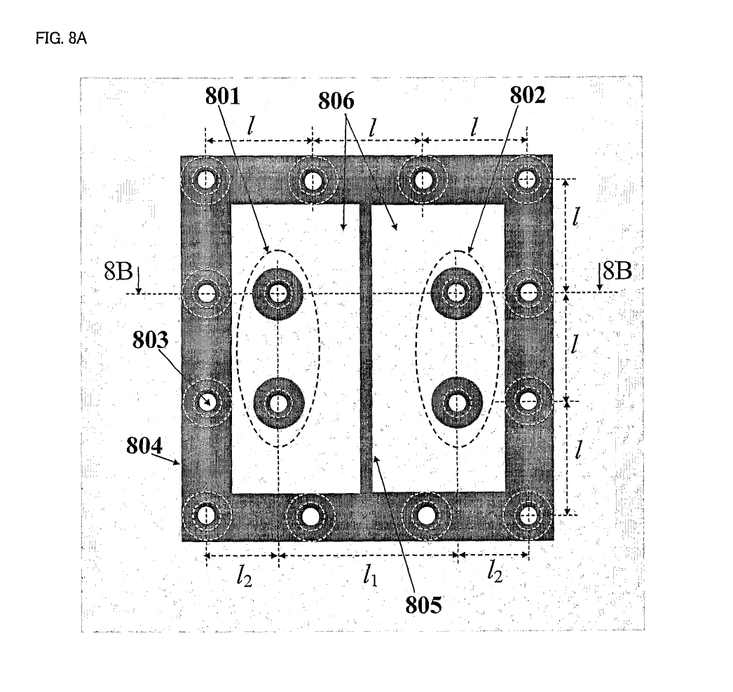

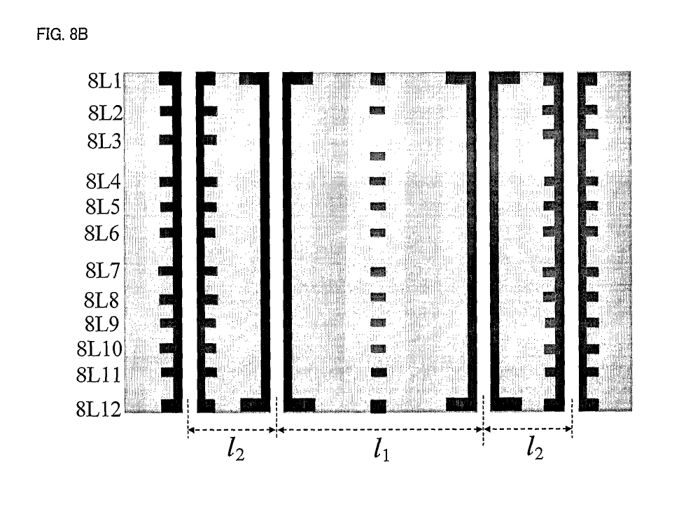

To provide the decrease of the crosstalk effect the distance between signal via pairs in a high-isolated via cell can be increased. In FIG. 8, the high-isolated cell with increased space between signal via pairs is shown. Here, the distance between the signal via pairs, I₁, is larger than the distance between the signal via pairs and shielding ground vias, I₂. It should be noted that minimal distance I₂ in a design of high-isolated cells can be defined according to a multilayer substrate fabrication process to provide isolation of signal vias from ground shielding.

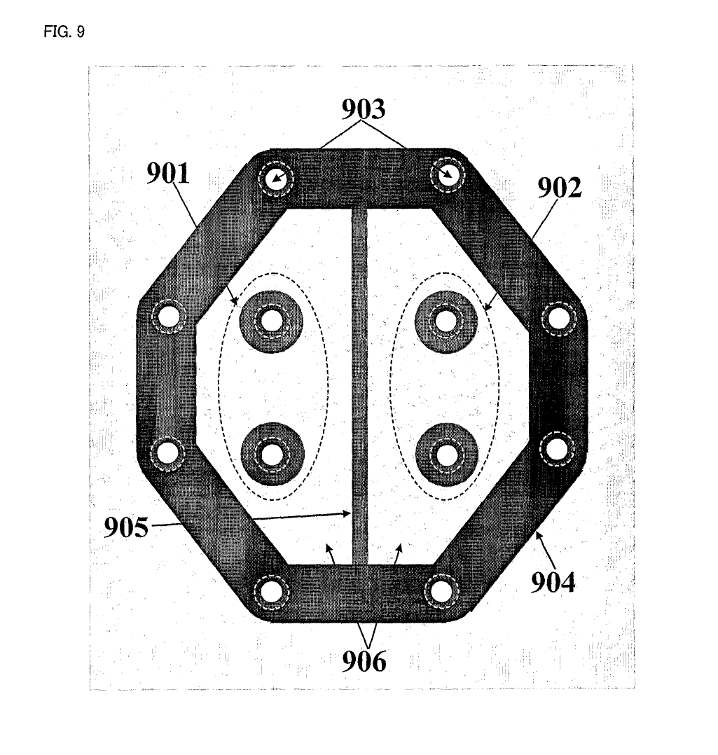

It is necessary to note that arrangement of ground vias around signal via pairs can be various but providing symmetrical location of two signal via pairs within ground shielding. This is an important point because it gives a possibility to minimize skew in differential signaling in vertical transitions due to equalization of the coupling between the signal via pair and ground via shield. Also, in this case, transformation between the differential mode and the common mode is reduced. In FIG. 9, another example of the ground via arrangement is shown.

In this invention, a method and structures providing high-performance differential signal propagation in the vertical direction of a multilayer substrate, that is, perpendicularly to planar conductor layers of the substrate are proposed. The method is based on the use of two main points: 1) Specific intercrossing differential signaling; 2) Ground shield around two signal via pairs.

The first point of the method gives an interior crosstalk reduction, that is, between two signal via pairs. This is provided by the intercrossing differential signaling in which four signal vias are disposed in vertexes of a square or a rhombus and two differential via pairs are formed by signal vias located on diagonals of the corresponding square or rhombus.

The second point leads to suppression of an exterior crosstalk between the signal via pairs and other interconnections in the multilayer substrate and, also, leakage from the signal via pairs by the use of the ground shield, that is very important in high-density design. It should be noted that the best performance of structures, formed according to the method, is achieved if the ground shield is formed symmetrically around the two signal via pairs to provide the same coupling effect between the signal via pairs and the ground shield.

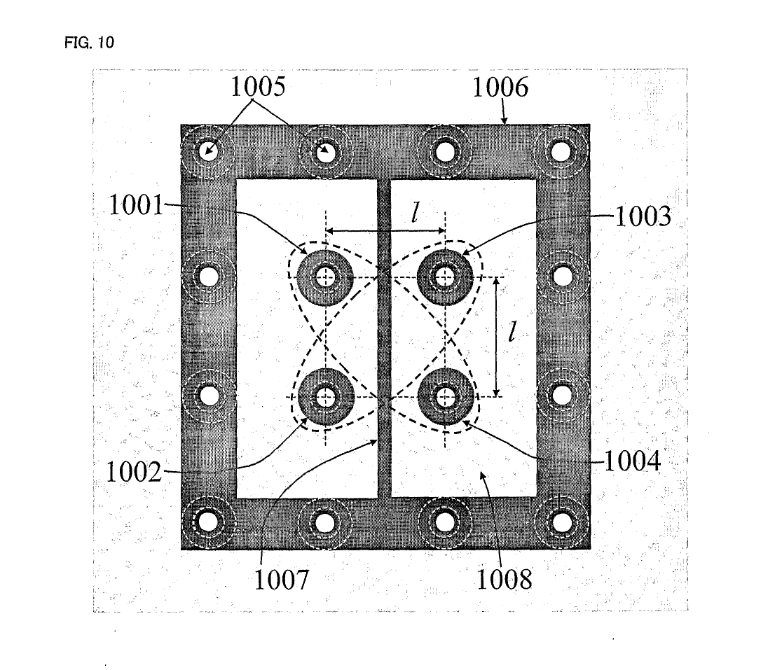

In FIG. 10, the horizontal cross-sectional view of an example of a high-isolated via cell designed according to above-mentioned method is presented. This structure is similar to the high-isolated cell shown in FIGS. 3A and 3B but four signal vias 1001, 1002, 1003 and 1004, arranged in a square form of side I, form intercrossing differential signaling via pairs in such way: One differential via pair consists of signal vias 1001 and 1004; Another differential via pair includes signal vias 1002 and 1003. Note these differential via pairs are disposed symmetrically within ground shield formed by ground vias 1005 and ground strip 1006.

Intercrossing differential signaling gives a possibility to reduce crosstalk effect between signal via pairs in the high-isolated via cell. This effect can be explained in the following manner. Crosstalk (unwanted) signals from one differential pair reaching each via of another differential pair are in the opposite polarity. Due to the square arrangement of signal vias and providing the same effect of ground shield on signal vias, the crosstalk signals from the differential via pair suppress each other.

Thus, a high-isolated via cell in a multilayer substrate realizing intercrossing differential signaling is a very important structure, because it can provide both a low crosstalk effect between differential pairs in this cell and also low coupling of the cell to other via structures disposed in the same multilayer substrate.

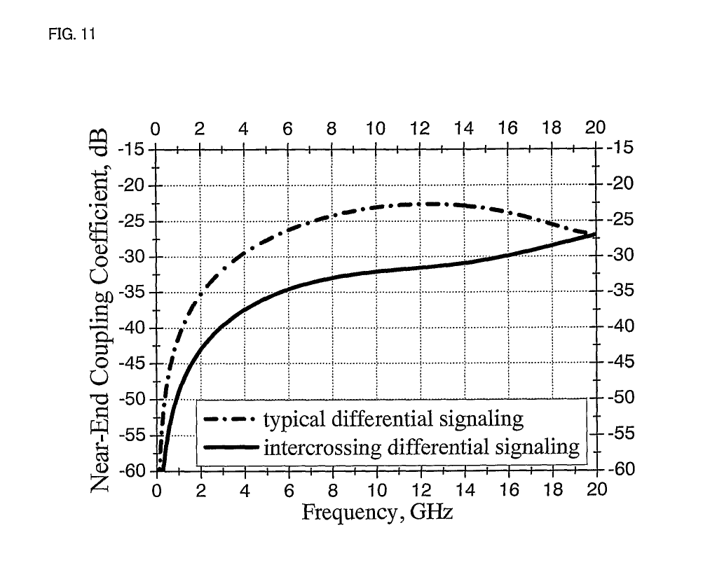

In FIG. 11, simulation data for crosstalk effect obtained for high-isolated via cells realizing both typical differential signaling (see FIG. 3A) and intercrossing (see FIG. 10) differential signaling are presented. The dimensions and structures of the high-isolated cells providing both types of the differential signaling are the same as for FIGS. 4A and 4B. As follows from FIG. 11, intercrossing differential signaling in the high-isolated via cell can considerably decrease crosstalk effect between differential pairs in the cell.

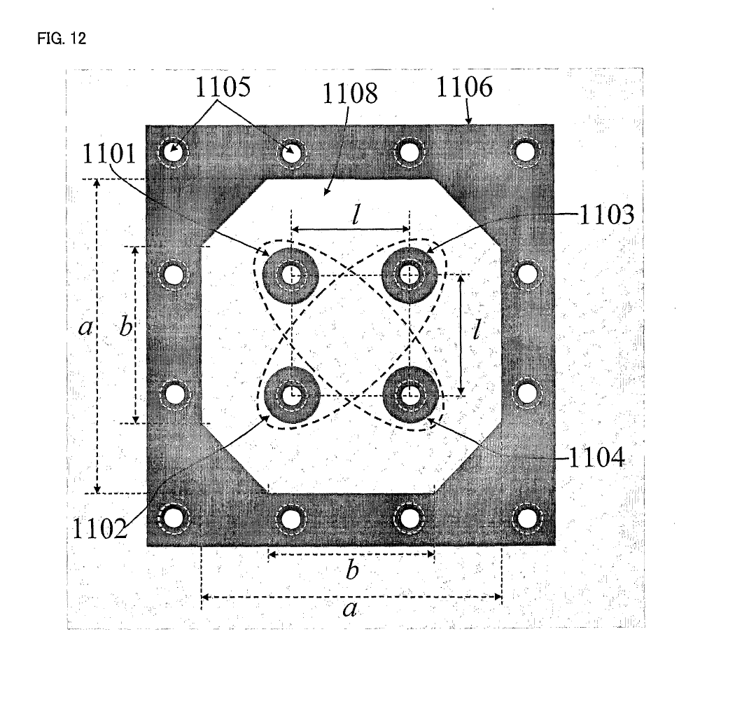

In some cases of the application of intercrossing differential signaling, a high-isolated via cell can be formed using above-mentioned points but without a separating strip between differential via pairs. An example of such via cells is shown in FIG. 12. In this figure, the high-isolated via cell is obtained by the use of four signal vias 1101, 1102, 1103 and 1104. Ground shield around these signal vias is formed by symmetrically ground vias 1105 connected by ground strips 1106. The clearance hole 1108 has transverse dimensions providing the isolation of the signal vias from the ground shield and a shape giving transverse dimensions of the ground strips 1106 as providing the same coupling effect of this strip to all signal vias. Note the specific shape of the clearance hole 1108 shown in the figure can be used to improve grounding of signal wiring at planar layers of a multilayer substrate and so on. In considered case signal vias 1101, 1102, 1103, and 1104 are arranged in such manner that an imaginary closed contour (dash line in the figure) passing through the centers the signal vias forms the square of side I. Intercrossing differential signaling is achieved as following: One signal via pair is formed by signal vias 1101 and 1104; Another signal via pair is obtained by signal vias 1102 and 1103.

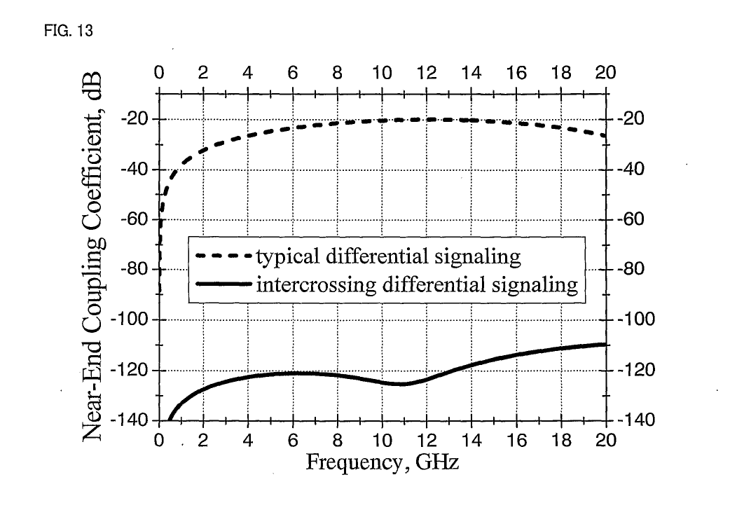

To demonstrate advantages of such type of high-isolated via cells, simulated data obtained for the cell designed in way as in FIG. 12 are presented in FIG. 13. In this figure, near-end coupling coefficients simulated by the finite-difference time-domain method are presented for both typical differential signaling and intercrossing differential signaling. Note that in simulations, typical differential signaling is formed by two signal pairs in which one pair is consisted of signal vias 1101 and 1102 and another pair includes signal vias 1103 and 1104. But intercrossing differential signaling is obtained as shown in FIG. 12. So, for presented data, the structure of the via cell is the same as in FIG. 10 as well as dimensions of the via cell and the multilayer PCB are the same as for FIGS. 4A and 4B except the transverse dimensions of the clearance hole. For considered via cell, following dimensions of the clearance hole 1108 (see FIG. 12) are used: a=2.5 mm and b=0.75 mm.

As follows from numerical data presented in FIG. 13, the use of intercrossing differential signaling and structures similar to the via cell shown in FIG. 12 can dramatically improve the electrical performance of high-density differential via interconnections embedded in a multilayer substrate by considerable reduction of the crosstalk effects.

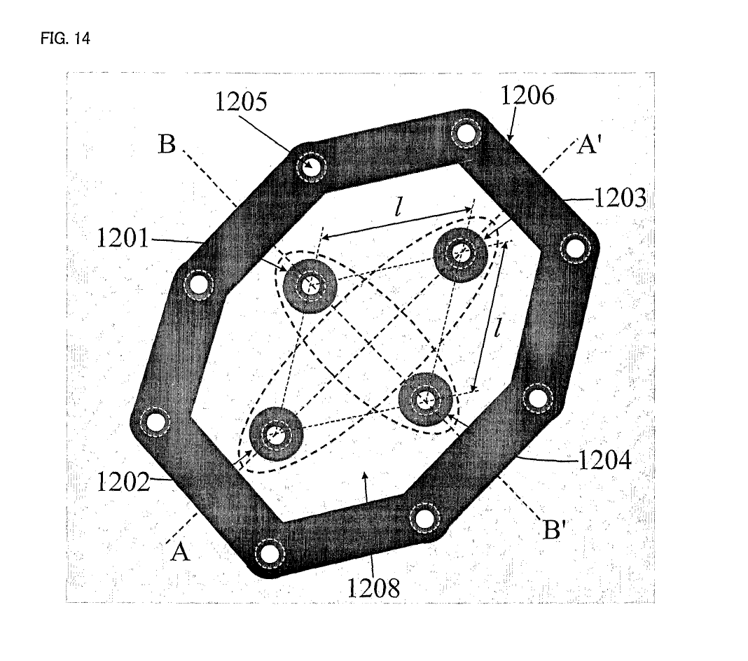

Another example of high-isolated via cells providing intercrossing differential signaling is presented in FIG. 14. In this figure, signal vias 1201, 1202, 1203, and 1204 are arranged in such manner that an imaginary closed contour shown a dash line in the figure passing through the centers the signal vias forms the rhombus of side I. Intercrossing differential signaling is achieved as following: One signal via pair is formed by signal vias 1201 and 1204 which are situated on the diagonal BB′; Another signal via pair is obtained by signal vias 1202 and 1203 which are disposed on the diagonal AA′. Note that in this case a separating strip is also not applied.

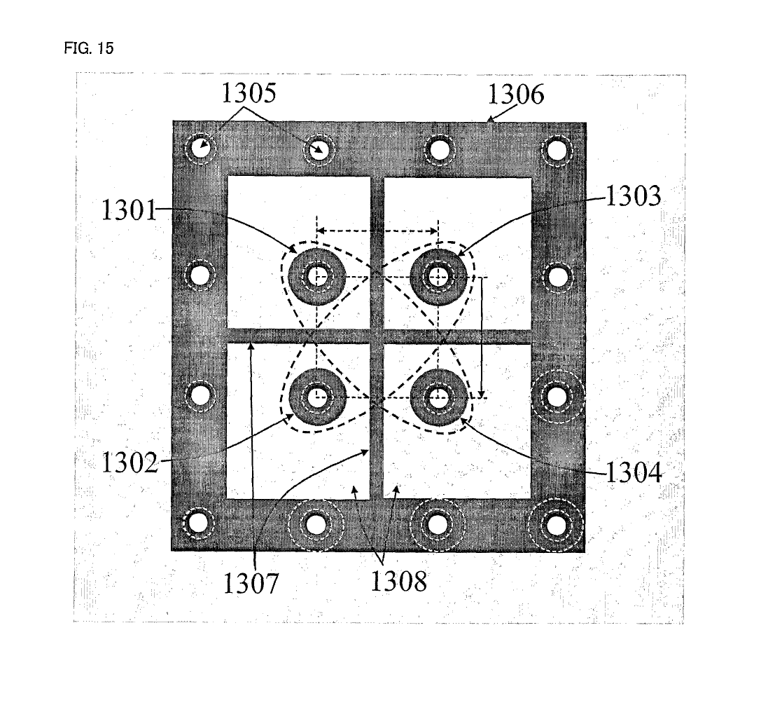

Also in the case of intercrossing differential signaling, a separating strip cross 1307 can be used in a high-isolated via cell. An example of such high-isolated via cells is demonstrated in FIG. 15.

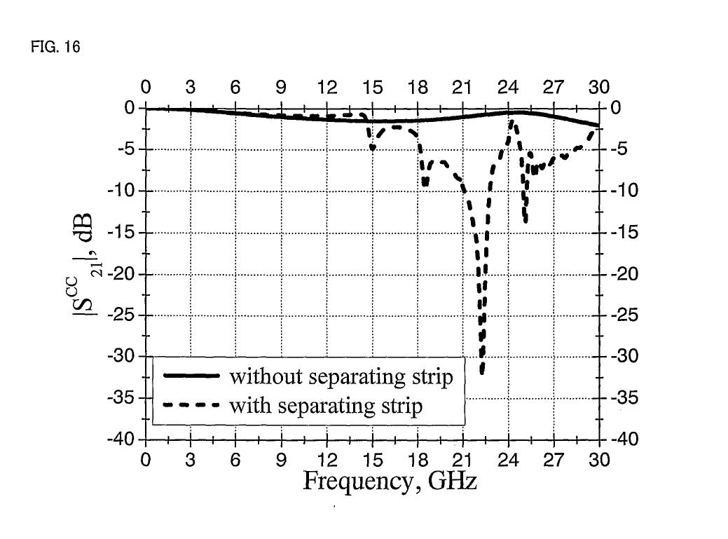

It should be noted that the use of a separating strip fabricated of an electromagnetic energy absorbing material in a high-isolated via cell can give such advantage as a reduction of the common mode in differential interconnection circuits disposed in a multilayer substrate. This is important to reduce noise in such circuits and leakage (radiation) from the multilayer substrate. In FIG. 16, insertion losses (|S₂₁^{CC}|)-parameter) are presented for the common mode propagated in the via cell with and without the separating strip of the electromagnetic energy absorbing material. Dimensions of the via cell and the multilayer PCB are the same as for the high-isolated via cell with the optimized clearance hole for which simulated data are demonstrated in FIGS. 4A and 4B. But, only in this case, the separating strip is made of the electromagnetic energy absorbing material with the relative permittivity of ∈ᵣ=40, the loss tangent electrical of tan δₑ=0.026, the relative permeability of μᵣ=1.2, and the loss tangent magnetic tan δₘ=1.5. The width of the separating strip in the high-isolated via cell is 0.3 mm. As follows from simulated data obtained by the finite-difference time-domain method, the magnitude of the common mode is reduced in the frequency band from about 15 GHz to about 30 GHz. Note that, at the same time, the magnitude of the differential mode is practically not changed.

Thus, a high-isolated via cell with a separating strip made of an energy absorbing material can reduce the magnitude of the common mode in differential interconnected circuits.

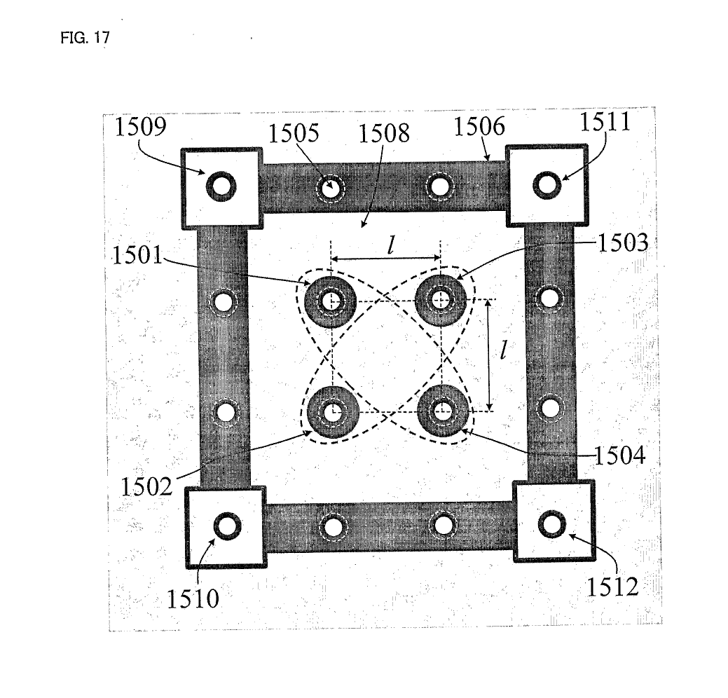

In FIG. 17, another high-isolated via cell with intercrossing differential signaling is presented. In this via cell, power supply vias 1509, 1510, 1511 and 1512 are arranged symmetrically in respect to both signal via pairs (one signal pair is formed by signal vias 1501 and 1504; another signal pair is obtained by signal vias 1502 and 1503) to provide the same coupling effect to the signal vias and, as a result, the higher electrical performance of this via cell.

It is clear that because invented high-isolated differential via cells can provide practically-independent differential signaling, then they can be used to form high-density via structures in a multilayer substrate combining required number of such cells.

According to another exemplary embodiment of the invention, there provided a design method of a via cell is proposed.

The design method according to another exemplary embodiment of the invention is a design method of a via cell comprising two signal via pairs in which signal vias are arranged so that an imaginary closed contour passing through the centers of the signal vias has the same side wherein two signal via pairs are formed by the signal vias disposed on the diagonal of the imaginary contour providing intercrossing differential signaling; a shield structure around two signal via pairs consisting of ground vias and ground strips connected to the ground vias wherein the shield structure is formed symmetrically in respect to two signal via pairs; and a clearance hole providing an isolation the signal via pairs from the shield structure filled in a non-conducting material.

The design method may also be configured such that the shield structure is formed by ground vias and ground strips connected to the ground vias as well as power supply vias which are disposed symmetrically with respect to two signal via pairs of the via cell and are surrounded by the ground strips.

According to another exemplary embodiment of the invention, there provided a wiring board is proposed.

The wiring board according to another exemplary embodiment of the invention is a wiring board comprising two signal via pairs including signal vias; a plurality of ground vias around two signal via pairs; a ground strip connected to a plurality of ground vias; and a separating structure separating the signal via pairs disposed between the signal via pairs.

The wiring board may also be configured such that the separating structure is a wiring connected to the ground vias disposed between the signal via pairs.

The wiring board may also be configured such that the separating structure is a dielectric disposed between the signal via pairs.

The wiring board may also be configured such that the separating structure is a magnetic substance disposed between the signal via pairs.

While the invention has been particularly shown and described with reference to exemplary embodiments thereof, the invention is not limited to these exemplary embodiments. It will be understood by those of ordinary skill in the art that various changes in form and details may be made therein without departing from the spirit and scope of the present invention as defined by the claims.

1. A multilayer substrate comprising a via cell wherein said via cell comprises:
two signal via pairs;
a shield structure around said two signal via pairs consisting of ground vias and ground strips connected to said ground vias formed symmetrically in respect to each signal via pair;
a separating strip disposed symmetrically between said two signal via pairs; and
a clearance hole providing an isolation said two signal via pairs from said shield structure, filled in a non-conducting material except the area of said separating strip, and having transverse dimensions larger than an area bounded by an imaginary contour tangentially connecting outer conductor boundaries of signal vias of said two signal via pairs.

2. The multilayer substrate according to claim 1, wherein
said separating strip is formed of a metal or an electromagnetic energy absorbing material.

3. The multilayer substrate according to claim 1, wherein
said shield structure is formed by ground vias and ground strips connected to said ground vias as well as power supply vias which are disposed symmetrically with respect to the nearest signal via pair of the via cell and are surrounded by said ground strips.

4. The multilayer substrate according to claim 1, wherein
the clearance hole has predetermined dimensions to provide a broadband operation of said via cell.

5. The multilayer substrate according to claim 1, wherein
an impedance matching of one signal via pair of the via cell and an interconnected circuit joined to said signal via pair is attained by adjusting diameters of vias of said signal via pair, the distance between vias of said signal via pair, the distance of said signal via pair to the shield structure, and transverse dimensions of the separating strip.

6. A multilayer substrate comprising a via cell wherein said via cell comprises:
two signal via pairs in which signal vias are arranged so that an imaginary closed contour passing through the centers of said signal vias has the same side, and each signal via pair of said two signal via pairs is formed by said signal vias disposed on the diagonal of said imaginary contour providing intercrossing differential signaling;
a shield structure around said two signal via pairs consisting of ground vias and ground strips connected to said ground vias wherein said shield structure is formed symmetrically in respect to said two signal via pairs; and
a clearance hole providing an isolation said two signal via pairs from said shield structure, filled in a non-conducting material, and having transverse dimensions larger than an area bounded by an imaginary contour tangentially connecting outer conductor boundaries of signal vias of said two signal via pairs.

7. The multilayer substrate according to claim 6, wherein
the imaginary closed contour passing through the centers of said signal vias has the same side shaping a square, and each signal via pair of said two signal via pairs is formed by said signal vias disposed on the diagonal of said square contour providing intercrossing differential signaling.

8. The multilayer substrate according to claim 6, wherein
the imaginary closed contour passing through the centers of said signal vias has the same side shaping a rhombus, and each signal via pair of said two signal via pairs is formed by said signal vias disposed on the diagonal of said rhombus providing intercrossing differential signaling.

9. The multilayer substrate according to claim 6, wherein
said shield structure is formed by ground vias and ground strips connected to said ground vias as well as power supply vias which are disposed symmetrically with respect to said two signal via pairs and are surrounded by said ground strips.

10. The multilayer substrate according to claim 6, wherein
a clearance hole has predetermined dimensions to provide broadband operation of the via cell.

11. The multilayer substrate according to claim 6, wherein
an impedance matching of one signal via pair of the via cell and an interconnected circuit joined to said signal via pair is attained by adjusting diameters of vias of said signal via pair, the distance between vias of said signal via pair, and the distance of said signal via pair to said shield structure.

12. A multilayer substrate comprising a high-isolated via cell wherein said high-isolated via cell comprises:
two signal via pairs in which signal vias are arranged so that an imaginary closed contour passing through the centers of said signal vias has the same side, and each signal via pair of said two signal via pairs is formed by said signal vias disposed on the diagonal of said imaginary contour providing intercrossing differential signaling;
a shield structure around said two signal via pairs consisting of ground vias and ground strips connected to said ground vias wherein said shield structure is formed symmetrically in respect to said two signal via pairs;
a separating strip cross disposed symmetrically between said two signal via pairs; and
a clearance hole providing an isolation said two signal via pairs from said shield structure, filled in a non-conducting material except the area of said separating strip cross, and having transverse dimensions larger than an area bounded by an imaginary contour tangentially connecting outer conductor boundaries of signal vias of said two signal via pairs.

13. The multilayer substrate according to claim 12, wherein
the imaginary closed contour passing through the centers of said signal vias has the same side shaping a square, and said two signal via pairs are formed by said signal vias disposed on the diagonal of said square contour providing intercrossing differential signaling.

14. The multilayer substrate according to claim 12, wherein
the imaginary closed contour passing through the centers of said signal vias has the same side shaping a rhombus, and said two signal via pairs are formed by said signal vias disposed on the diagonal of said rhombus providing intercrossing differential signaling.

15. The multilayer substrate according to claim 12, wherein
said separating strip cross is formed of an electromagnetic energy absorbing material.

16. The multilayer substrate according to claim 12, wherein
said shield structure is formed by ground vias and ground strips connected to said ground vias as well as power supply vias which are disposed symmetrically with respect to said two signal via pairs and are surrounded by said ground strips.

17. The multilayer substrate according to claim 12, wherein
a clearance hole has predetermined dimensions to provide broadband operation of the via cell.

18. The multilayer substrate according to claim 12, wherein
an impedance matching of one signal via pair of the via cell and an interconnected circuit joined to said signal via pair is attained by adjusting diameters of vias of said signal via pair, the distance between vias of said signal via pair, the distance of said signal via pair to said shield structure, and transverse dimensions of the separating strip cross.

19. A design method of a via cell comprising:
two signal via pairs in which signal vias are arranged so that an imaginary closed contour passing through the centers of said signal vias has the same side wherein said two signal via pairs are formed by said signal vias disposed on the diagonal of said imaginary contour providing intercrossing differential signaling;
a shield structure around said two signal via pairs consisting of ground vias and ground strips connected to said ground vias wherein said shield structure is formed symmetrically in respect to said two signal via pairs; and
a clearance hole providing an isolation said signal via pairs from said shield structure filled in a non-conducting material.

20. The design method according to claim 19, wherein
said shield structure is formed by ground vias and ground strips connected to said ground vias as well as power supply vias which are disposed symmetrically with respect to said two signal via pairs of the via cell and are surrounded by said ground strips.

21. A wiring board comprising:
two signal via pairs including signal vias;
a plurality of ground vias around said two signal via pairs;
a ground strip connected to said plurality of ground vias; and
a separating structure separating said signal via pairs disposed between said signal via pairs.

22. The wiring board according to claim 21, wherein
said separating structure is a wiring connected to said ground vias disposed between said signal via pairs.

23. The wiring board according to claim 21, wherein
said separating structure is a dielectric disposed between said signal via pairs.

24. The wiring board according to claim 21, wherein
said separating structure is a magnetic substance disposed between said signal via pairs.
